(19) United States
(12) Patent Application Publication
(10) Pub. No.: US 2026/0018407 A1
(43) Pub. Date: Jan. 15, 2026

(54) METHODS FOR TUNABLE DIELECTRIC THICKNESS OF A SEMICONDUCTOR SUBSTRATE USING BACK SURFACE HEATING

(71) Applicant: GlobalWafers Co., Ltd., Hsinchu (TW)

(72) Inventors: WangHua Lin, Hsinchu County (TW); Dong-Peng Chen, Changhua County (TW); JenYu Lin, Hsinchu City (TW); WeiTing Chen, Hsinchu County (TW); ChunWei Hsu, Zhubei City (TW); Yung Hsing Chu, Zhubei City (TW); Liang-Chin Chen, Zhubei City (TW)

(21) Appl. No.: 19/265,436

(22) Filed: Jul. 10, 2025

Related U.S. Application Data
(60) Provisional application No. 63/669,788, filed on Jul. 11, 2024.

(51) Int. Cl. H01L 21/02; C23C 22/48

(52) U.S. Cl. CPC H01L 21/02236; C23C 22/48

(57) ABSTRACT

Described herein is a method of growing a dielectric layer on a surface of a single crystal semiconductor substrate. The method includes providing the single crystal semiconductor substrate, the single crystal semiconductor substrate including two major, generally parallel surfaces, one of which is a front surface of the single crystal semiconductor substrate and the other of which is a back surface of the single crystal semiconductor substrate, a circumferential edge joining the front and back surfaces, and a bulk region between the front and back surfaces, contacting the front surface with an oxidizing solution including an oxidizing agent, and simultaneously, contacting the back surface with a heat source that facilitates increasing a reaction rate between the oxidizing agent and the front surface.

### CROSS-REFERENCE TO RELATED APPLICATIONS

This application claims priority to U.S. Provisional Patent Application No. 63/669,788, filed Jul. 11, 2024, the disclosure of which is hereby incorporated by reference in its entirety.

### BACKGROUND

In semiconductor manufacturing, the first layer that is formed on a semiconductor substrate is often the thermal dielectric (e.g., thermal oxide) layer. The dielectric layer of the semiconductor substrate plays a crucial role in controlling the dielectric layer thickness with minimal deviation. Some integrated circuit (IC) manufacturers reset the surface dielectric layer through additional oxide etching and formation processes, but this approach poses cost challenges. Many IC manufacturers choose to grow the dielectric layer without any pre-treatment process. It is a key problem to control the final dielectric layer thickness and properties to ensure that the dielectric layer thickness will meet a target thickness after processing.

The dielectric layer can be formed using oxidation processes such as oxide deposition (e.g., plasma enhanced chemical vapor deposition (PECVD) in an N₂O atmosphere), thermal oxidation (e.g., rapid thermal annealing (RTA) in an oxidizing atmosphere), or hot deionized (DI) water treatment. PECVD using N₂O and RTA treatments do not easily control the dielectric layer thickness in a narrow range, and require additional processes to control the dielectric layer thickness. And hot DI water only provides a nominal thickness build and requires very long treatment time.

Semiconductor substrate cleaning tools can typically be divided into two types: wet bench and single semiconductor substrate cleaner (SWC). During the cleaning process, the surface dielectric layer can be etched by known chemical solutions such as Standard Clean 1 (SC1) solution (i.e., a combination of deionized water, NH₄OH, and H₂O₂), HF, FPM, etc., and formed by H₂O₂, SC1, ozone water or aqueous ozone (O₃ W), etc. The wet bench and SWC types are shown and described in U.S. Patent No. 7, 456, 113, issued Nov. 25, 2008, the entire contents of which are hereby incorporated by reference herein. The wet bench type may include steps of HF etch, rinse, SC1, rinse, Standard Clean 2 (SC2), rinse, and dry. The SWC type may include steps of HF etch, rinse, chemical clean, rinse, and dry. The wet bench and SWC types typically result in chemical oxide thicknesses of about 10.8 Å and 9.9 Å, respectively. Consequently, SWC types are typically insufficient for providing thicker chemical oxides.

Thus, there is a need for improved SWC processes to adjust the chemical oxide composition and thickness of semiconductor substrate oxide or dielectric layers.

### BRIEF DESCRIPTION

In one aspect, described herein is a method of growing a dielectric layer on a surface of a single crystal semiconductor substrate. The method includes providing the single crystal semiconductor substrate, the single crystal semiconductor substrate including two major, generally parallel surfaces, one of which is a front surface of the single crystal semiconductor substrate and the other of which is a back surface of the single crystal semiconductor substrate, a circumferential edge joining the front and back surfaces, and a bulk region between the front and back surfaces, contacting the front surface with an oxidizing solution including an oxidizing agent, and simultaneously, contacting the back surface with a heat source that facilitates increasing a reaction rate between the oxidizing agent and the front surface.

### BRIEF DESCRIPTION OF THE DRAWINGS

These and other features, aspects, and advantages of the present disclosure will become better understood when the following detailed description is read with reference to the accompanying drawings in which like characters represent like parts throughout the drawings, wherein:

FIG. 1 is a cross-section of an example semiconductor substrate suitable for use in methods of processing single crystal semiconductor substrates in accordance with the present disclosure.

FIG. 2 depicts an exemplary process flow suitable for use in methods of processing single crystal semiconductor substrates in accordance with the present disclosure.

FIG. 3 depicts chemical oxide thickness achieved by growth under different chemical conditions in accordance with the present disclosure.

FIG. 4 depicts oxide thickness by different O₃ concentration treatments in accordance with the present disclosure. All treatments were carried out at a temperature of 22° C. and a pH of 4.6. The trendlines are labeled with the applied concentrations of ozone water.

FIG. 5 depicts a single semiconductor substrate cleaner configuration in accordance with the present disclosure.

FIG. 6 depicts a spray nozzle layout for a cleaner design having multiple nozzles in accordance with the present disclosure.

Unless otherwise indicated, the drawings provided herein are meant to illustrate features of embodiments of the disclosure. These features are believed to be applicable in a wide variety of systems comprising one or more embodiments of the disclosure. As such, the drawings are not meant to include all conventional features known by those of ordinary skill in the art to be required for the practice of the embodiments disclosed herein.

### DETAILED DESCRIPTION

Described herein are methods of growing a dielectric layer on a surface of a semiconductor substrate. The methods control dielectric layer thickness on the semiconductor substrate by varying the concentration and temperature characteristics of an oxidizing solution.

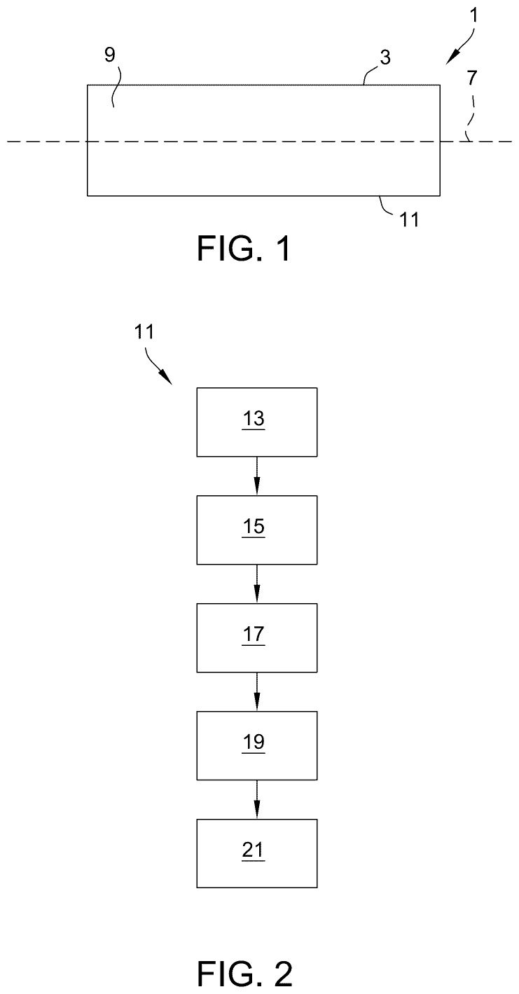

Referring now to FIG. 1, a semiconductor substrate 1 has a front surface 3, a back surface 5, an imaginary central plane 7 between the front and back surfaces, and a semiconductor substrate bulk 9 comprising the semiconductor substrate volume between the front and back surfaces. The single crystal semiconductor substrate 1 may also be referred to as a wafer. Further, while the single crystal semiconductor substrate 1 is described throughout the present disclosure as a silicon substrate, the single crystal semiconductor substrate 1 may include other semiconductor substrates, materials, or layers, including, for example and without limitation, silicon, germanium, gallium arsenide, aluminum nitride, silicon germanium, gallium nitride, indium gallium arsenide, silicon nitride, silicon carbide, and combinations thereof.

The single crystal semiconductor substrate 1 may be a single crystal silicon wafer sliced from a single crystal ingot grown in accordance with Czochralski (CZ) or float zone growing methods. Such methods, as well as standard silicon slicing, lapping, etching, and polishing techniques are disclosed, for example, in F. Shimura, Semiconductor Silicon Crystal Technology, Academic Press, 1989, and Silicon Chemical Etching, (J. Grabmaier ed.) Springer-Verlag, N.Y., 1982 (incorporated herein by reference).

Single crystal silicon wafers may be obtained from commercial suppliers, such as GlobalWafers Co., Ltd., Taiwan. The wafers may be sliced from an ingot using any suitable technique (e.g., a wire saw operation). In various embodiments, the single crystal semiconductor substrate 1 is sliced substantially on-axis from a single crystal silicon ingot. The phrase “substantially on-axis” as used herein to describe semiconductor substrates sliced from a single crystal silicon ingot means that the slicing angle at which the semiconductor substrates are sliced has minimal on-axis deviation (e.g., less than +/−0.1°, preferably less than +/−0.07°, in an x-axis direction and in a y-axis direction) from the crystal direction that is normal to the crystallographic orientation of the ingot (i.e., along a central longitudinal axis of the ingot). Although single crystal silicon wafers having any crystallographic orientation (e.g., {100}, {110} or {111}) may be used as the single crystal semiconductor substrate 1, {100} silicon wafers will be described to illustrate a semiconductor substrate that is sliced substantially on-axis from the ingot in accordance with the present disclosure. The {100} silicon wafers may, in some implementations, be sliced from a {100} silicon ingot at an angle that deviates from the direction (e.g., at an angle between about 0.1° to about 0.5° off the central longitudinal axis of the ingot in an x-axis and/or y-axis direction). These {100} silicon wafers sliced at an angle that deviates from the direction in the x-axis and/or the y-axis direction may have less haze after being annealed than wafers sliced substantially along (e.g., deviating less than +/−0.1° in the x-axis direction and in the y-axis direction from) the direction. However, post-anneal, nanometer-sized recesses that affect surface roughness may be absent from silicon device layers derived from epitaxial silicon layers formed on single crystal semiconductor substrate 1 that have been sliced substantially on-axis from the ingot. These post-anneal, nanometer-sized recesses may otherwise exist where the silicon device layer is derived from a single crystal semiconductor substrate 1 that has been sliced off-axis from an ingot. Accordingly, the single crystal semiconductor substrate 1 is, in some embodiments, sliced substantially on-axis from a single crystal silicon ingot. In these embodiments, the on-axis deviation of the slicing angle (i.e., the deviation of the slicing angle from the central longitudinal axis of the ingot in the x-axis direction and in the y-axis direction) at which the single crystal semiconductor substrate 1 is sliced from a single crystal silicon ingot is preferably less than +/−0.1°, and more preferably less than +/−0.07°. In some embodiments, the single crystal semiconductor substrate 1 is sliced precisely along (i.e., at an angle that does not deviate in either the x-axis direction or the y-axis direction from) the crystal direction that is normal to the crystallographic orientation of the ingot. For example, {100} silicon wafers used for the single crystal semiconductor substrate 1 may be sliced from a {100} silicon ingot precisely along the direction.

Referring now to FIG. 2, an example process flow 11 for processing a semiconductor substrate, such as the single crystal semiconductor substrate 1 shown in FIG. 1, is shown. The process flow includes a pre-cleaning step 13, a growth step 15, an edge strip step 17, a polishing step 19, and a defect inspection step 21. This exemplary process flow is illustrative and does not limit the depicted process steps or the order of these steps, nor does it exclude other process steps. For example, the methods of the present disclosure may be used with other backside treatment process, such as one or more of rapid thermal annealing (RTA), epitaxy (EPI), chemical vapor deposition (CVD), physical vapor deposition (PVD), dry etching, furnace processing, and cleaning. Relevant process steps are described in more detail, for example, in US Patent No. 10, 832, 938, US Patent No. 11, 798, 802, US Patent Publication No. 2024/0258156, US Patent Publication No. 2025/0069945, US Patent Publication No. 2024/0258155, and US Patent Publication No. 2022/0359195, the entire contents of which are hereby incorporated by reference herein.

The pre-cleaning step 13 prepares the single crystal semiconductor substrate for treatment. This pre-cleaning step 13 may include any suitable cleaning step known in the art that facilitates the method described herein. In some embodiments, the wafers are polished and cleaned by standard methods known to those skilled in the art. See, for example, W. C. O'Mara et al., Handbook of Semiconductor Silicon Technology, Noyes Publications. If desired, the wafers can be cleaned, for example, in a conventional Standard Clean 1 (SC1)/Standard Clean 2 (SC2) solution. In some embodiments, pre-cleaning step 13 comprises treating a surface of the single crystal semiconductor substrate to remove contaminants (e.g., organic compound contaminants and other contaminant particles deposited on the wafer during an implantation process). Treating the surface may include washing with a solvent, exposing the surface to a reducing agent, exposing the surface to an etching agent, or a combination thereof.

The growth step 15 grows a dielectric layer (e.g., an oxide layer) on the semiconductor substrate. The dielectric layer may be any electrically insulating material suitable for use that facilitates the method described herein. Generally, the dielectric layer includes an oxide. Exemplary dielectric materials include SiO₂, Si₃N₄, aluminum oxide, and magnesium oxide. The growth step 15 controls dielectric layer thickness on the semiconductor substrate by varying the concentration and temperature characteristics of an oxidizing solution. The growth step 15 is described in more detail below.

The edge strip step 17 strips the edge of the material layer grown in the growth step 15. This step removes unwanted materials from a periphery of the semiconductor substrate. This step avoids defect-free edges.

The polishing step 19 smooths the front surface of the semiconductor substrate and reduces defects. The polishing step 19 may be a final polishing step or a non-final polishing step. For example, the semiconductor substrate may be subjected to a chemical mechanical polishing (CMP) operation such that a front surface, and optionally a back surface, of the semiconductor substrate are smoothed to a targeted shape and flatness. After polishing, the semiconductor substrate may have a mirror-polished surface finish that is free from surface defects, such as scratches and large particles.

The defect inspection step 21 analyzes the semiconductor substrate for surface defects (e.g., scratches and large particles) and dimples. The defect inspection step 21 may be conducted with any suitable metrology technique known in the art that facilitates the method described herein.

The example process flow 11 may include further steps not depicted, including pre-processing steps and post-processing steps.

For example, the example process flow 11 may further include growing an epitaxial layer on the front surface of the single crystal semiconductor substrate. A grown epitaxial layer may comprise substantially the same electrical characteristics as the underlying single crystal semiconductor substrate. Alternatively, the epitaxial layer may comprise different electrical characteristics as the underlying single crystal semiconductor substrate. An epitaxial layer may comprise a material selected from the group consisting of silicon, silicon carbide, silicon germanium, gallium arsenide, gallium nitride, indium phosphide, indium gallium arsenide, germanium, and combinations thereof. Depending upon the desired properties of the final device, the epitaxial layer may comprise electrically active dopants, such as boron (p type), gallium (p type), aluminum (p type), indium (p type), phosphorus (n type), antimony (n type), and arsenic (n type). The resistivity of the epitaxial layer may range from 1 to 50 Ohm-cm, typically, from 5 to 25 Ohm-cm. In some embodiments, the epitaxial layer may have a thickness between about 20 nanometers and about 3 micrometers, such as between about 20 nanometers and about 2 micrometers, such as between about 20 nanometers and about 1.5 micrometers or between about 1.5 micrometers and about 3 micrometers.

In many embodiments, method of growing a dielectric layer on a surface of a single crystal semiconductor substrate is disclosed. The method includes providing the single crystal semiconductor substrate, the single crystal semiconductor substrate including two major, generally parallel surfaces, one of which is a front surface of the single crystal semiconductor substrate and the other of which is a back surface of the single crystal semiconductor substrate, a circumferential edge joining the front and back surfaces, and a bulk region between the front and back surfaces, contacting the front surface with an oxidizing solution including an oxidizing agent, and simultaneously, contacting the back surface with a heat source that facilitates increasing a reaction rate between the oxidizing agent and the front surface.

In some embodiments, the semiconductor substrate comprises a material selected from the group consisting of silicon, germanium, gallium arsenide, aluminum nitride, silicon germanium, gallium nitride, indium gallium arsenide, silicon nitride, silicon carbide, and combinations thereof.

In some embodiments, the semiconductor substrate comprises silicon. In some embodiments, the semiconductor substrate is a silicon semiconductor substrate. In some embodiments, the semiconductor substrate is a single crystal silicon semiconductor substrate.

The semiconductor substrate may be any diameter suitable for use by those of skill in the art including, for example, about 200 mm, about 300 mm, greater than about 300 mm or even about 450 mm diameter substrates.

The single crystal semiconductor substrate may have any resistivity obtainable by the CZ or float zone methods. The resistivity of the substrate may vary based on the requirements of the end use/application of the semiconductor substrate. The resistivity may vary from milliohm or less to megaohm or more. “High resistivity” substrates have a minimum bulk resistivity of at least 500 Ohm-cm, such as between 500 Ohm-cm to 100,000 Ohm-cm. “Low resistivity” substrates have a minimum bulk resistivity of below (less than or equal to) 500 Ohm-cm, such as between 1 Ohm-cm to 100 Ohm-cm. Methods for preparing wafers of varying resistivities are known in the art, and wafers having a desired resistivity may be obtained from commercial suppliers, such as GlobalWafers Co., Ltd., Taiwan.

In some embodiments, the substrate has a minimum bulk resistivity of at least 500 Ohm-cm, at least 1000 Ohm-cm, or at least 3000 Ohm-cm, such as between 500 Ohm-cm and 100,000 Ohm-cm. In some embodiments, the single crystal semiconductor substrate has a minimum bulk region resistivity in a range of from about 0.005 ohm-cm to about 500 ohm-cm. In some embodiments, the single crystal semiconductor substrate has a minimum bulk region resistivity of at least about 0.005 Ohm-cm. The bulk region resistivity may be altered via dopants.

Generally, the oxidizing agent may include any suitable oxidizing agent that facilitates the method described herein. In some embodiments, the oxidizing agent includes ozone. In some embodiments, the oxidizing agent includes hydrogen peroxide (H₂O₂).

Generally, the oxidizing solution may include any suitable oxidizing solution that facilitates the method described herein. In some embodiments, the oxidizing solution is an ozone solution. In some embodiments, a solvent of the oxidizing solution is selected from the group consisting of water, aqueous solvents, non-aqueous solvents, and combinations thereof. In some embodiments, the oxidizing solution is ozone water. In some embodiments, the oxidizing solution is a hydrogen peroxide solution.

Generally, the ozone solution may include ozone in any suitable concentration that facilitates the method described herein. In some embodiments, the ozone solution comprises ozone in an amount of from about 0.01 ppm to about 100 ppm. In some embodiments, the ozone solution comprises ozone in an amount of from about 10 ppm to about 50 ppm. In some embodiments, the ozone solution comprises ozone in an amount of from about 5 ppm to about 40 ppm. In some embodiments, the ozone solution comprises ozone in an amount of at least about 20 ppm.

In many embodiments, the heat source comprises a hot liquid. Generally, the hot liquid may include any suitable hot liquid that facilitates the method described herein. In some embodiments, the hot liquid is selected from the group consisting of water, NH₄OH, dilute NH₄OH, H₂O₂, dilute H₂O₂, HCl, dilute HCl, and combinations thereof.

The hot liquid is readily adjusted by controlling the concentrations and/or mixing ratios of the individual components.

In some embodiments, water is present in the hot liquid in a range of from about 80 wt % to about 99.9 wt %.

In some embodiments, non-water components are each individually present in the hot liquid in a concentration in a range of from about 0 wt % to about 5 wt %. In some embodiments, non-water components are each individually present in the hot liquid in a concentration in a range of from about 0.1 wt % to about 5 wt %.

In some embodiments, NH₄OH is present in the hot liquid in a concentration in a range of from about 0.1 wt % to about 5 wt %. In some embodiments, dilute NH₄OH is present in the hot liquid in a concentration in a range of from about 0.1 wt % to about 5 wt %.

In some embodiments, H₂O₂ is present in the hot liquid in a concentration in a range of from about 0.1 wt % to about 5 wt %.

In some embodiments, HCl is present in the hot liquid in a concentration in a range of from about 0.1 wt % to about 5 wt %. In some embodiments, dilute HCl is present in the hot liquid in a concentration in a range of from about 0.1 wt % to about 5 wt %.

In some embodiments, NH₄OH and H₂O₂ are each present in the hot liquid in a concentration in a range of from about 0.1 wt % to about 5 wt %.

In some embodiments, HCl and H₂O₂ are each present in the hot liquid in a concentration in a range of from about 0.1 wt % to about 5 wt %.

In some embodiments, the hot liquid comprises water, NH₄OH, and H₂O₂. In some embodiments, the hot liquid is SC1 solution.

In some embodiments, the hot liquid comprises water, HCl, and H₂O₂. In some embodiments, the hot liquid is SC2 solution.

In some embodiments, the hot liquid is water.

In some embodiments, the hot liquid is dilute NH₄OH.

In some embodiments, the hot liquid is dilute H₂O₂.

In some embodiments, the hot liquid is dilute HCl.

Generally, the heat source may be at any suitable temperature that facilitates the method described herein.

In some embodiments, the heat source is at a temperature of at least about 25° C., at least about 30° C., at least about 35° C., at least about 40° C., at least about 45° C., at least about 50° C., at least about 55° C., at least about 60° C., at least about 65° C., at least about 70° C., at least about 75° C., at least about 80° C., at least about 85° C., or at least about 90° C.

In some embodiments, the heat source is at a temperature of at most about 30° C., at most about 35° C., at most about 40° C., at most about 45° C., at most about 50° C., at most about 55° C., at most about 60° C., at most about 65° C., at most about 70° C., at most about 75° C., at most about 80° C., at most about 85° C., at most about 90° C., or at most about 95° C.

In some embodiments, the heat source is at a temperature in a range of from about 25° C. to about 95° C. In some embodiments, the heat source is at a temperature in a range of from about 45° C. to about 95° C. In some embodiments, the heat source is at a temperature in a range of from about 65° C. to about 95° C.

In some embodiments, the heat source heats the semiconductor substrate to a temperature of at least about 25° C., at least about 30° C., at least about 35° C., at least about 40° C., at least about 45° C., at least about 50° C., at least about 55° C., at least about 60° C., at least about 65° C., at least about 70° C., at least about 75° C., at least about 80° C., at least about 85° C., or at least about 90° C.

In some embodiments, the heat source heats the semiconductor substrate to a temperature of at most about 30° C., at most about 35° C., at most about 40° C., at most about 45° C., at most about 50° C., at most about 55° C., at most about 60° C., at most about 65° C., at most about 70° C., at most about 75° C., at most about 80° C., at most about 85° C., at most about 90° C., or at most about 95° C.

In some embodiments, the heat source heats the semiconductor substrate to a temperature in a range of from about 25° C. to about 95° C. In some embodiments, the heat source heats the semiconductor substrate to a temperature in a range of from about 45° C. to about 95° C. In some embodiments, the heat source heats the semiconductor substrate to a temperature in a range of from about 65° C. to about 95° C. Generally, the semiconductor substrate is at a lower temperature than the heat source due to application of the oxidizing solution to the front surface of the semiconductor substrate.

In some embodiments, the oxidizing solution is at room temperature. In some embodiments, the oxidizing solution is at a temperature in a range of from about 20° C. to about 25° C.

The heat source may also be provided to the semiconductor substrate as an additional or alternative localized heating mechanism that facilitates increasing a reaction rate between the oxidizing agent and the front surface. Generally, heating may occur via any suitable localized heating mechanism that facilitates the method described herein. Exemplary localized heating mechanisms include radiative heaters, conductive heaters, convective heaters, heat lamps, infrared lighting, lasers, and combinations thereof.

In some embodiments, heating of the semiconductor substrate is symmetrical. In these embodiments, it is understood that the temperature of the heated semiconductor substrate is substantially uniform (e.g., within 10%) across the front side of the semiconductor substrate.

In some embodiments, the method is performed using a single semiconductor substrate cleaning tool.

In some embodiments, the dielectric layer is grown to a thickness of at least 3 Å, at least 4 Å, at least 5 Å, at least 6 Å, at least 7 Å, at least 8 Å, at least 9 Å, at least 10 Å, or at least 11 Å in a time of at most about 20 minutes. In some embodiments, the dielectric layer is grown to a thickness of at least 3 Å, at least 4 Å, at least 5 Å, at least 6 Å, at least 7 Å, at least 8 Å, at least 9 Å, at least 10 Å, or at least 11 Å in a time of at most about 10 minutes.

In some embodiments, the dielectric layer is grown to a thickness of at most 4 Å, at most 5 Å, at most 6 Å, at most 7 Å, at most 8 Å, at most 9 Å, at most 10 Å, at most 11 Å, or at most 12 Å in a time of at most about 20 minutes. In some embodiments, the dielectric layer is grown to a thickness of at most 4 Å, at most 5 Å, at most 6 Å, at most 7 Å, at most 8 Å, at most 9 Å, at most 10 Å, at most 11 Å, or at most 12 Å in a time of at most about 10 minutes.

In some embodiments, the dielectric layer is grown to a thickness of at least 9 Å in a time of at most about 20 minutes. In some embodiments, the dielectric layer is grown to a thickness of at least 11 Å in a time of at most about 20 minutes.

In some embodiments, the dielectric layer is grown to a thickness of at least 9 Å in a time of at most about 10 minutes. In some embodiments, the dielectric layer is grown to a thickness of at least 11 Å in a time of at most about 10 minutes.

Generally, the oxidizing agent concentration can be used to control thickness and rate of thickness growth.

Generally, contacting the front surface with an oxidizing solution including an oxidizing agent and contacting the back surface with a hot liquid that facilitates increasing a reaction rate between the oxidizing agent and the front surface each may occur via any suitable technique that facilitates the method described herein. In some embodiments, contacting is achieved by spraying each of the oxidizing solution and the hot liquid onto the semiconductor substrate.

### EXAMPLES

Without further elaboration, it is believed that one skilled in the art using the preceding description can utilize the present invention to its fullest extent. The following Examples are, therefore, to be construed as merely illustrative, and not limiting of the disclosure in any way whatsoever. The starting material for the following Examples may not have necessarily been prepared by a particular preparative run whose procedure is described in other Examples. It also is understood that any numerical range recited herein includes all values from the lower value to the upper value. For example, if a range is stated as 10-50, it is intended that values such as 12-30, 20-40, or 30-50, etc., are expressly enumerated in this specification. These are only examples of what is specifically intended, and all possible combinations of numerical values between and including the lowest value and the highest value enumerated are to be considered to be expressly stated in this application.

### Example 1. Formation of a Surface Dielectric Layer with Ozone (O₃) Water

In this example, chemical oxide thickness was adjusted by the following process sequence: chemical clean, hot O₃W, rinse, and dry. Control mechanisms may be provided to control flow rate and temperature of the O₃W and the hot liquid. If semiconductor substrate unexpected temperature or flow rate errors occur during the semiconductor substrate process, the thickness of the surface oxide may shift.

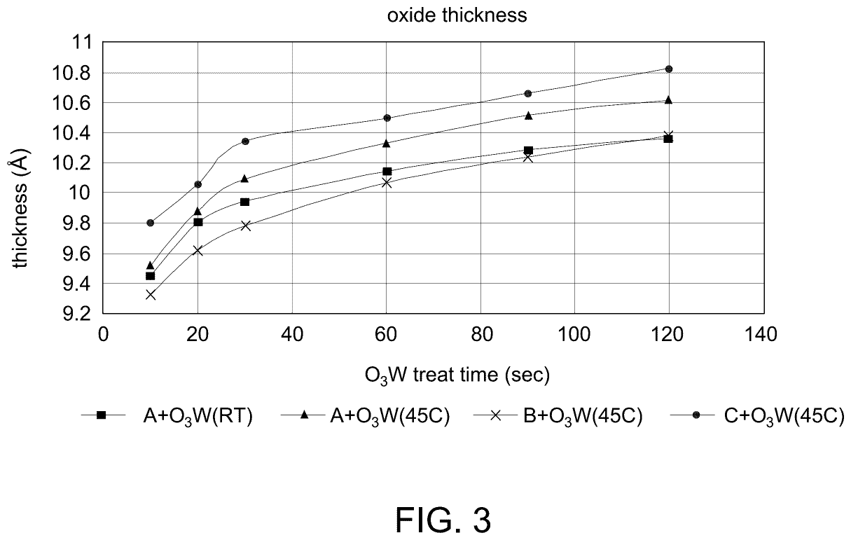

FIG. 3 depicts oxide thickness curves based on different chemical process and O₃W spray durations. The oxide thickness slightly increased after 30 seconds of O₃W spray.

In FIG. 3, A+O₃W (RT) means chemical oxide A subjected to an O₃W treatment at room temperature, A+O₃W (45C) means chemical oxide A subjected to an O₃W treatment at 45° C. heating, B+O₃W (45C) means chemical oxide B subjected to an O₃W treatment at 45° C. heating, and C+O₃W (45C) means chemical oxide C subjected to an O₃W treatment at 45° C. heating.

Chemical oxides may be grown with different treatments (e.g., A, B, or C) in the same process tool. For example, both SC1 and O₃W can grow chemical oxide on a surface and either SC1 treatment then O₃W treatment or O₃W treatment then SC1 treatment will yield a different chemical oxide.

Without being bound to any particular theory, it is believed that oxides are formed immediately when O radicals touch the Si surface. The O₃W provides O radicals, which react with Si atoms in two ways. In one way, O radicals penetrate through the dielectric layer and react with semiconductor substrate surface Si atoms. In the other way, O radicals react with partially bonded Si atoms in the bulk oxide. Therefore, the oxide thickness is slightly increased and the film structure became denser.

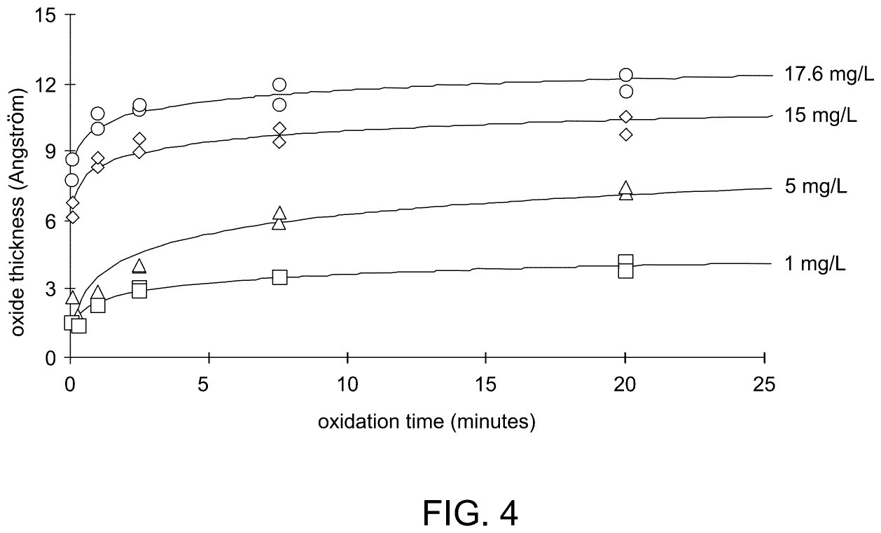

As shown in FIG. 4, higher O₃ concentration without heating can result in a higher oxide thickness, but it requires a very long time to reach saturation level. All treatments were carried out at a temperature of 22° C. and a pH of 4.6. The trendlines are labeled with the applied concentrations of ozone water, which range from 1 mg/L to 17.6 mg/L.

To reduce the time to saturation, the present disclosure utilizes hot liquid to heat the semiconductor substrate and accelerate the diffusion of O radicals before the structure becomes denser.

### Example 2. Cleaner Design

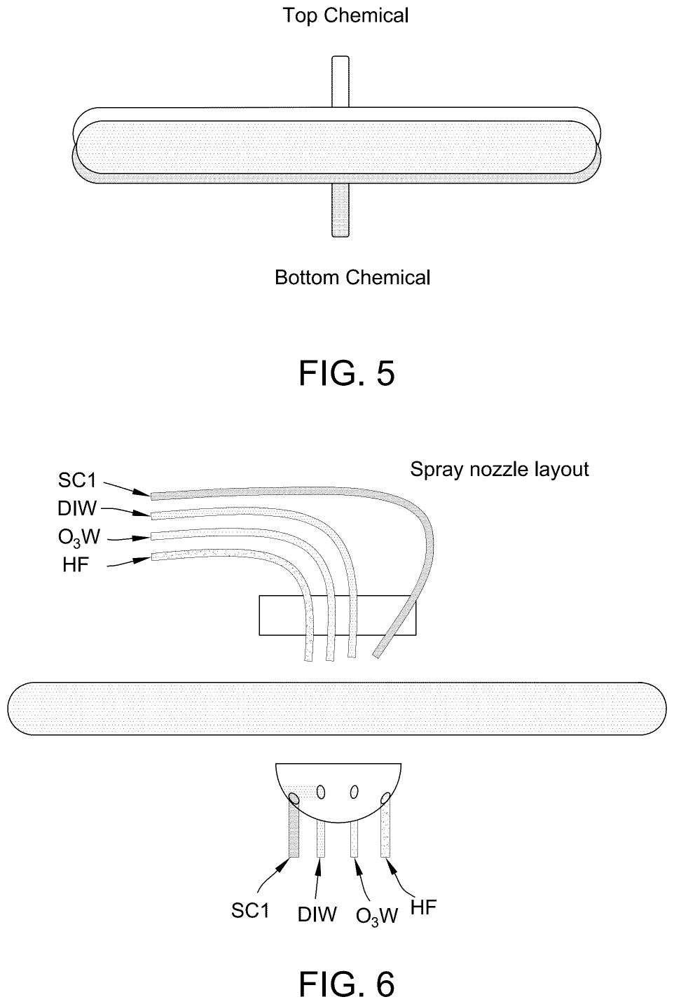

During a comparative wet bench procedure, the semiconductor substrate is dipped in a tank where both sides encounter the same chemical solution. In contrast, a single semiconductor substrate cleaner process can control the top and bottom sides of the semiconductor substrate with different chemical solutions. In this case, backside hot liquid is used to heat the semiconductor substrate during top side O₃W treatment. Such a configuration is shown in FIG. 5.

### Example 3. Cleaner Design Having Multiple Nozzles

A single semiconductor substrate cleaner process with a cleaner design having multiple nozzles is easy to switch chemicals in less than 0.5 seconds. This design forms different dielectric layers by using various components such as O₃W, H₂O₂, and SC1 through recipe sequence settings. Such a configuration is shown in FIG. 6.

O₃ oxide can be formed by applying a sequence of O₃ W, HF, and O₃W.

SC1 oxide can be formed by applying a sequence of SC1, HF, and SC1 or long SC1.

O₃/SC1 oxide can be formed by applying a sequence of O₃W, optional HF, SC1, optional HF, and O₃W.

In any of the above sequences, each of the steps can be readily modified to use any chemical solution as desired.

### SUMMARY

Described herein are methods of growing a dielectric layer on a surface of a semiconductor substrate. The methods control dielectric layer thickness on the semiconductor substrate by varying the concentration and temperature characteristics of an oxidizing solution.

### Definitions.

As used herein, references to “example embodiment” or “one embodiment” or “some embodiments” of the present disclosure are not intended to be interpreted as excluding the existence of additional embodiments that also incorporate the recited features.

As used herein, the terms “about,” “substantially,” “essentially” and “approximately” when used in conjunction with ranges of dimensions, concentrations, temperatures or other physical or chemical properties or characteristics is meant to cover variations that may exist in the upper and/or lower limits of the ranges of the properties or characteristics, including, for example, variations resulting from rounding, measurement methodology or other statistical variation.

When introducing elements of the present disclosure or the embodiment(s) thereof, the articles “a,” “an,” “the,” and “said” are intended to mean that there are one or more of the elements. The terms “comprising,” “including,” “containing,” and “having” are intended to be inclusive and mean that there may be additional elements other than the listed elements. The use of terms indicating a particular orientation (e.g., “top,” “bottom,” “side,” etc.) is for convenience of description and does not require any particular orientation of the item described.

As various changes could be made in the above constructions and methods without departing from the scope of the disclosure, it is intended that all matter contained in the above description and shown in the accompanying drawing [s] shall be interpreted as illustrative and not in a limiting sense.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

### Exemplary Embodiments

1. A method of growing a dielectric layer on a surface of a single crystal semiconductor substrate, the method comprising:
providing the single crystal semiconductor substrate, the single crystal semiconductor substrate comprising two major, generally parallel surfaces, one of which is a front surface of the single crystal semiconductor substrate and the other of which is a back surface of the single crystal semiconductor substrate, a circumferential edge joining the front and back surfaces, and a bulk region between the front and back surfaces;
contacting the front surface with an oxidizing solution including an oxidizing agent; and
simultaneously, contacting the back surface with a heat source that facilitates increasing a reaction rate between the oxidizing agent and the front surface.

2. The method of any preceding clause, wherein the oxidizing agent is ozone.

3. The method of any preceding clause, wherein the oxidizing solution is an ozone solution.

4. The method of the preceding clause, wherein the ozone is present in a concentration of from about 0.01 ppm to about 100 ppm.

5. The method of any preceding clause, wherein the ozone is present in a concentration of at least about 20 ppm.

6. The method of any preceding clause, wherein the oxidizing solution is ozone water.

7. The method of any preceding clause, wherein the heat source comprises a hot liquid is selected from the group consisting of water, NH₄OH, dilute NH₄OH, H₂O₂, dilute H₂O₂, HCl, dilute HCl, and combinations thereof.

8. The method of the preceding clause, wherein the hot liquid comprises water, NH₄OH, and H₂O₂.

9. The method of any preceding clause, wherein the hot liquid is Standard Clean 1 (SC1) solution.

10. The method of any preceding clause, wherein the hot liquid is water.

11. The method of any preceding clause, wherein the hot liquid is dilute NH₄OH.

12. The method of any preceding clause, wherein the hot liquid is dilute H₂O₂.

13. The method of any preceding clause, wherein the heat source is at a temperature in a range of from about 25° C. to about 95° C.

14. The method of any preceding clause, wherein the heat source heats the single crystal semiconductor substrate to a temperature in a range of from about 25° C. to about 95° C.

15. The method of any preceding clause, wherein the method is performed using a single semiconductor substrate cleaning tool.

16. The method of any preceding clause, wherein the single crystal semiconductor substrate has a minimum bulk region resistivity of between about 0.005 Ohm-cm and 500 Ohm-cm.

17. The method of any preceding clause, wherein the dielectric layer is grown to a thickness of at least 9 Å in a time of at most about 20 minutes.

18. The method of any preceding clause, wherein the dielectric layer is grown to a thickness of at least 11 Å in a time of at most about 20 minutes.

19. The method of any preceding clause, wherein the dielectric layer is grown to a thickness of at least 9 Å in a time of at most about 10 minutes.

20. The method of any preceding clause, wherein the dielectric layer is grown to a thickness of at least 11 Å in a time of at most about 10 minutes.

The individual aspects of the present disclosure may be combined in any combination or permutation. Select exemplary embodiments are set forth in the following clauses. These embodiments are non-limiting.

What is claimed is:

1. A method of growing a dielectric layer on a surface of a single crystal semiconductor substrate, the method comprising:
providing the single crystal semiconductor substrate, the single crystal semiconductor substrate comprising two major, generally parallel surfaces, one of which is a front surface of the single crystal semiconductor substrate and the other of which is a back surface of the single crystal semiconductor substrate, a circumferential edge joining the front and back surfaces, and a bulk region between the front and back surfaces;
contacting the front surface with an oxidizing solution including an oxidizing agent; and
simultaneously, contacting the back surface with a heat source that facilitates increasing a reaction rate between the oxidizing agent and the front surface.

2. The method of claim 1, wherein the oxidizing agent is ozone.

3. The method of claim 1, wherein the oxidizing solution is an ozone solution.

4. The method of claim 3, wherein the ozone is present in a concentration of from about 0.01 ppm to about 100 ppm.

5. The method of claim 3, wherein the ozone is present in a concentration of at least about 20 ppm.

6. The method of claim 1, wherein the oxidizing solution is ozone water.

7. The method of claim 1, wherein the heat source comprises a hot liquid selected from the group consisting of water, NH₄OH, dilute NH₄OH, H₂O₂, dilute H₂O₂, HCl, dilute HCl, and combinations thereof.

8. The method of claim 7, wherein the hot liquid comprises water, NH₄OH, and H₂O₂.

9. The method of claim 7, wherein the hot liquid is Standard Clean 1 (SC1) solution.

10. The method of claim 7, wherein the hot liquid is water.

11. The method of claim 7, wherein the hot liquid is dilute NH₄OH.

12. The method of claim 7, wherein the hot liquid is dilute H₂O₂.

13. The method of claim 1, wherein the heat source is at a temperature in a range of from about 25° C. to about 95° C.

14. The method of claim 1, wherein the heat source heats the single crystal semiconductor substrate to a temperature in a range of from about 25° C. to about 95° C.

15. The method of claim 1, wherein the method is performed using a single semiconductor substrate cleaning tool.

16. The method of claim 1, wherein the single crystal semiconductor substrate has a minimum bulk region resistivity of between about 0.005 Ohm-cm and 500 Ohm-cm.

17. The method of claim 1, wherein the dielectric layer is grown to a thickness of at least 9 Å in a time of at most about 20 minutes.

18. The method of claim 1, wherein the dielectric layer is grown to a thickness of at least 11 Å in a time of at most about 20 minutes.

19. The method of claim 1, wherein the dielectric layer is grown to a thickness of at least 9 Å in a time of at most about 10 minutes.

20. The method of claim 1, wherein the dielectric layer is grown to a thickness of at least 11 Å in a time of at most about 10 minutes.
